(19) United States
(12) Patent Application Publication
(10) Pub. No.: US 2018/0238950 A1
(43) Pub. Date: Aug. 23, 2018

(54) MONITORING SYSTEM AND CABLE

(71) Applicant: LEONI KABEL GMBH, Nuernberg (DE)

(72) Inventors: ERWIN KOEPPENDOERFER, SCHWABACH (DE); MARKUS SCHILL, MUENCHEN (DE)

(21) Appl. No.: 15/899,568

(22) Filed: Feb. 20, 2018

(30) Foreign Application Priority Data
Feb. 17, 2017 (DE) 10 2017 202 631.6

(51) Int. Cl. G01R 31/02; G01R 27/26; G01M 3/18

(52) U.S. Cl. CPC G01R 31/021; H04B 3/46; G01M 3/181; G01R 27/26

(57) ABSTRACT

A monitoring system includes an evaluation unit and a cable which has a cable core around which a multilayer sheath is disposed. The multilayer sheath has an inner and an outer electrode of a capacitor. A hygroscopic intermediate layer is disposed between the two electrodes. The evaluation unit is configured to monitor the cable for moisture based on the capacitance of the capacitor. A cable is also provided.

### CROSS-REFERENCE TO RELATED APPLICATION

This application claims the benefit, under 35 U.S.C. § 119, of German Patent Application DE 10 2017 202 631.6, filed Feb. 17, 2017; the prior application is herewith incorporated by reference in its entirety.

### BACKGROUND OF THE INVENTION

### Field of the Invention

The invention relates to a monitoring system and a cable.

Cables are used generally for transmitting data or for supplying connected components, for example, with (electrical) energy, media, etc. The serviceability of the cable also depends on the external environmental conditions, such as for example an external temperature loading.

In addition, the occurrence of moisture and its penetration into a cable is particularly critical. Although, as a rule, cables and lines are constructed in such a way that penetration of water is avoided as far as possible, it cannot be ruled out completely. In principle, moisture or water can enter in many ways. That can take place from an end face, for example as a result of inadequate seals on the connector, or through the longitudinal side as a result of damage in the outer sheath.

### SUMMARY OF THE INVENTION

It is accordingly an object of the invention to provide a monitoring system and a cable, which overcome the hereinafore-mentioned disadvantages of the heretofore-known systems and cables of this general type and which are able to detect undesired penetration of moisture as early as possible in a cable.

With the foregoing and other objects in view there is provided, in accordance with the invention, a monitoring system including an evaluation unit and a cable. The cable in turn has a cable core around which a multilayer sheath is disposed. The multilayer sheath has an inner electrode and an outer electrode, which form a capacitor. A hygroscopic intermediate layer is disposed between the two electrodes. The evaluation unit is connected to the two electrodes and is constructed to monitor the cable for moisture by using the capacitance of the capacitor.

The placement of the hygroscopic intermediate layer between the two electrodes is of substantial importance. In the event of the penetration of moisture, the intermediate layer absorbs moisture. As a result, the capacitance of the capacitor is changed. This capacitance change is measured directly or indirectly by the monitoring system. Furthermore, the monitoring system is configured to draw conclusions about the condition of the cable with regard to penetrated moisture from a changed capacitance. For this purpose, the monitoring system falls back, for example, on stored comparative values or an algorithm, which draws conclusions about the penetrated moisture from the capacitance.

The intermediate layer preferably has a swellable material and, in particular, is formed of such a swellable material, so that the absorption of moisture leads to a change in the spacing between the electrodes and therefore to a change in the capacitance of the capacitor. In one refinement, in which the intermediate layer is formed by the swellable material, the swellable material is disposed exclusively between the two electrodes.

A material which has a so-called superabsorber or is formed from the superabsorber is in particular used for the intermediate layer. Such superabsorbers are synthetic materials which are capable of absorbing a multiple of their inherent weight or volume of polar liquids. As the liquid is absorbed, the superabsorber swells and forms a hydrogel. Such superabsorbers are known in principle and are used, for example, in the hygiene sector or in building materials. Thus, for example, swellable thermoplastic elastomers are known which have superabsorbers as constituent parts, for example, and can be processed like thermoplastic elastomers and therefore, for example, can be extruded.

In a dry initial state of the intermediate layer, the electrodes preferably are disposed at a distance from each other in the range of <0.1 mm. The spacing corresponds to the thickness of the intermediate layer. This comparatively low thickness permits a significant change in the capacitance, since even slight thickness changes lead to considerable capacitance changes. In this case, a dry initial state is understood to mean a defined state with a defined moisture value, which the swellable material exhibits under normal environmental conditions. In particular, a dry initial state is understood to mean a residual moisture of <5%.

With regard to providing the most unambiguous possible evaluation possibility and, associated therewith, with regard to the highest possible capacitance change, the thickness increases by at least a factor of 10 or at least a factor of 20 until a moist final state is reached. In turn, a moist final state is understood to mean the state of maximum water absorption capacity of the swellable material, that is to say at 100% moisture.

Expediently, the electrodes extend over the entire length of the cable. According to one expedient refinement, at least one and preferably both electrodes are formed in the manner of a screen layer. The electrodes are therefore cylindrical and typically disposed concentrically with respect to the cable core. The configuration in the manner of screen layers is simple to implement in production terms, since for this purpose recourse can be made in this case to conventional fabrication methods for forming conventional screen layers. In principle, different types of screen layers can be used to form the electrodes. These are, for example, foil screens, braided screens or helical cable screens.

In a preferred refinement, at least one of the electrodes, specifically the inner electrode, is formed as a braid or a helix. In general terms, this at least one electrode is constructed to be water-permeable. This is in principle given in the case of a braid or a helix. Through the use of this measure, water which has penetrated into the cable can pass through the electrode in the direction toward the intermediate layer. If, for example, water penetrates at the end, then this frequently propagates in the axial direction in the boundary layers between two layers. As a result of the water-permeable formation of the at least one electrode, radial moisture transport toward the intermediate layer is also made possible, which ultimately supports the reliable detection of moisture.

In order to form the intermediate layer, it is expediently extruded onto the inner electrode. Conventional methods (extrusion methods) known in cable production can also be used for this purpose.

In addition to the formation of the intermediate layer as an extruded intermediate layer, there is in principle also the possibility to form the latter as a foil wound around the inner electrode and made of a correspondingly suitable material. Alternatively, the foil includes a carrier material having a hygroscopic layer applied thereto and having the swellable material.

Due to the increasing volume of the intermediate layer, in a preferred refinement the sheath has an outer sheath layer made of an elastic, extensible material. For example, the material used for the outer sheath layer is a thermoplastic elastomer (TPE), a PVC or a mixture of a TPE and PVC. The TPE being used is in particular a TPE-S (styrene block polymer) or alternatively a TPE-O (olefin-based TPE, in particular PP/EPDM) or a TPE-U (urethane-based TPE).

According to an expedient refinement, the cable has only the two electrodes for the evaluation of the capacitance of the capacitor. The cable therefore preferably has no inductance within the cable to which the electrodes are wired. The cable therefore has, overall, a comparatively simple structure. Specifically, no further (coil) wires are disposed between the two electrodes.

In principle, different methods are available for the evaluation of the capacitance change caused by the swelling of the intermediate layers. According to a first preferred refinement, the evaluation unit is configured for the direct measurement of the capacitance. For this purpose, a standard capacitance measurement, such as for example the known dual-slope method or a bridge circuit, is used.

According to an alternative variant, the electrodes forming the capacitor are connected to an additional external inductance located in the evaluation unit, so that a tuned circuit is formed. The evaluation unit is preferably further constructed to determine the resonant frequency of the tuned circuit. Since, in the event of a change in the capacitance of the capacitor, the tuned circuit is de-tuned and the resonant frequency changes, in this way a very accurate statement about the change of the capacitance value and therefore about the distance between the electrodes can be made, at least indirectly.

According to a further preferred refinement, the evaluation unit is ultimately constructed to output and feed a measuring signal into the cable and the propagation time of the measuring signal is evaluated. This configuration is based on the thought that the propagation time of a high-frequency measuring signal depends on the impedance (wave resistance) of a medium in which the wave and therefore the measuring signal propagates. The impedance in turn depends on the capacitance. To this extent, a capacitance change therefore influences the propagation time of a high-frequency measuring signal. In this case, the measuring signal is fed into one of the electrodes.

According to a first refinement, for this purpose, for example, measuring pulses are fed in. Reflected proportions of the measuring pulses are generated at a line end and monitoring is carried out to see whether superimposition of the measuring pulses with the reflected proportions is present at a predefined measuring point, wherein, depending on the superimposition, a deviation of the propagation time from a previously known propagation time, and therefore a deviation from a normal state, is detected. Such a method is described, for example, in German Patent Application DE 10 2016 210 610.5.

In a preferred further refinement, a pulse-like measuring signal (square-wave pulse), for example, is sent in and a reflected proportion is monitored inasmuch as a digital stop signal is generated when a threshold value is exceeded. In this case, a propagation time between the starting time and the stop signal is measured. Specifically, in this case a stop pattern characterizing the line is generated, is compared with a reference pattern for a normal state of the line and is checked for a deviation. Such a method can be gathered from German Patent Application DE 10 2016 222 233.3.

All of these measuring methods are used for the direct or indirect determination of the capacitance or the capacitance change, which represents a measure in particular of the changed spacing between the two electrodes and generally a measure of the absorption of moisture. The evaluation unit is constructed to output an error signal if there is a deviation of a measured value or a value derived from the measured value from a predefined target value. The measured value is in particular the capacitance.

With the objects of the invention in view, there is also provided a cable including a cable core around which a multilayer sheath is disposed, the multilayer sheath has an inner electrode and an outer electrode of a capacitor and a hygroscopic intermediate layer made of a swellable material is disposed between the two electrodes.

The advantages and preferred refinements listed with regard to the monitoring system can also be transferred to the cable in an analogous way.

In particular in a preferred refinement, the evaluation unit previously described is already integrated into the cable, specifically in a connector fastened to one cable end. The evaluation unit is connected to the capacitor and constructed to determine the capacitance of the latter. Also preferably integrated in the connector is a data interface, through which an error message is transmitted to a higher-order control unit in the event of a fault.

Other features which are considered as characteristic for the invention are set forth in the appended claims.

Although the invention is illustrated and described herein as embodied in a monitoring system and a cable, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE SEVERAL VIEWS OF THE DRAWING

FIG. 1 is a diagrammatic, exemplary cross-sectional view of a cable;

FIG. 2 is a highly-simplified, longitudinal-sectional view of a measurement structure; and

FIG. 3 is a highly-simplified, side-elevational view of a cable with a connector having an integrated evaluation unit fastened to the end.

### DETAILED DESCRIPTION OF THE INVENTION

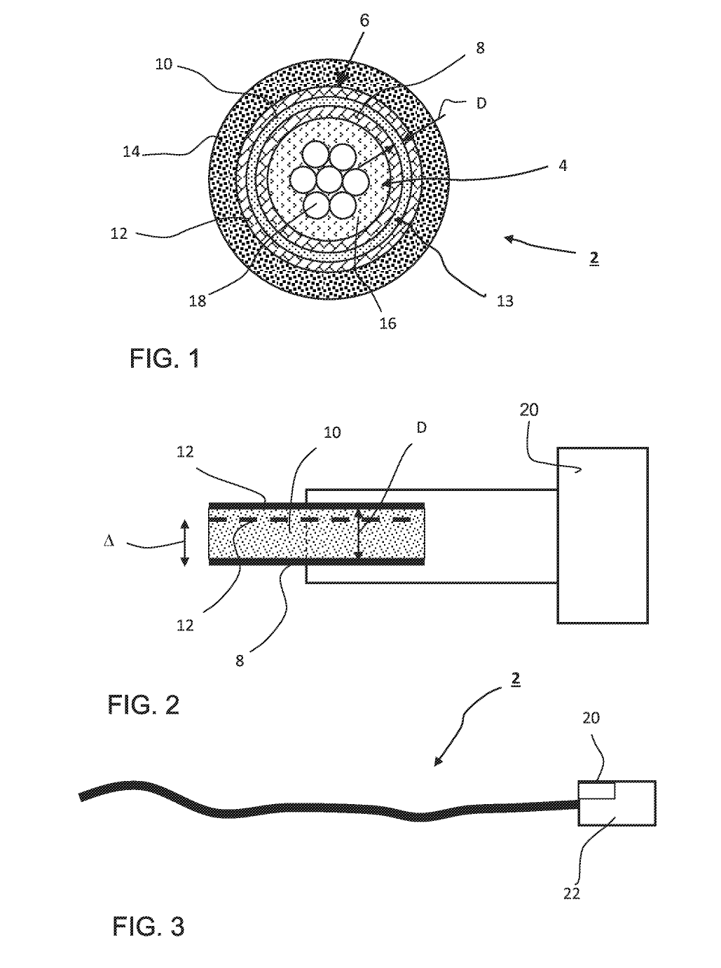

Referring now in detail to the figures of the drawings, in which parts acting in the same way are provided with the same designations, and first, particularly, to FIG. 1 thereof, there is seen a cable 2 that has an inner central cable core 4, which is surrounded by a multilayer sheath 6. A first layer of this multilayer sheath 6 is an inner electrode 8, which is surrounded concentrically by an intermediate layer 10, which is in turn surrounded concentrically by an outer electrode 12. The two electrodes 8, 12 form a capacitor 13 with the intermediate layer 10. Finally, the cable 2 also has an outer sheath 14 on the outside.

The cable core 4 can in principle have an extremely wide range of configurations. In the exemplary embodiment of FIG. 1, the cable core 4 is formed as a wire having a conductor 18 which is surrounded by an insulation 16 and which, in the exemplary embodiment, is formed as a stranded wire. Alternatively, the cable core is, for example, a data transmission core having multiple data transmission lines which, for example, are twisted in pairs or untwisted and are formed with or without a pair screen. In principle, the specific configuration of the cable core does not matter in the present case. In general, electrical and/or optical transmission elements or else media conduits (hoses) are disposed within the cable core 4.

The two electrodes 8, 12 are each formed as screen layers disposed concentrically with respect to each other. In particular, the inner electrode 8 is moisture-permeable and specifically formed as a braided screen or helical screen. The outer electrode 12 is, for example, likewise formed as a braided screen or helical screen. Alternatively, it is formed as a screen foil or has a screen foil, so that a certain amount of sealing is achieved, in order for example to avoid the penetration of moisture into the inner cable structure.

The intermediate layer has a thickness D. This thickness D preferably lies in the range <0.1 mm and in particular in the range from about 20 μm to 70 μm and, for example, around 50 μm. The thickness D simultaneously corresponds to a spacing of the two electrodes 8, 12 relative to each other.

The intermediate layer 10 has a swellable material or is formed by such a swellable material. Specifically, the intermediate layer 10 has a superabsorber as a swellable material. Such superabsorbers are known in principle.

The aforementioned thickness D in the range <0.1 mm relates to the thickness D in a dry initial state of the intermediate layer 10. In the event of the penetration of moisture, the intermediate layer 10 swells, so that the thickness D and therefore the distance between the two electrodes 8, 12 increases considerably. The distance increases by a factor of 10 to 20 from the dry initial state up to a moist final state of the intermediate layer. In a moist final state, the swellable material has absorbed the maximum amount of moisture.

As a result of this pronounced distance change, the capacitance of the capacitor 13 formed by the two electrodes 8, 12 decreases considerably. This capacitance change is measured and evaluated.

A measuring configuration, which is illustrated in a highly simplified manner, is shown in FIG. 2. In FIG. 2, it is possible to see firstly the two electrodes 8, 12 and an evaluation unit 20 which is connected to the two electrodes 8, 12. The capacitance of the capacitor 13 is determined by the evaluation unit 20 as previously described. In the left-hand half of FIG. 2, only the capacitor formed by the two electrodes 8, 12 with the intermediate layer 10 of the swellable material is illustrated. A dashed line indicates the position of the outer electrode 12 in the initial state, and a continuous line indicates the position of the outer electrode 12 in a moist final state. The original distance between the two electrodes 8, 12 increases considerably by a distance change Δ.

FIG. 3, finally, shows by way of example a side illustration of a cable 2 with a connector 22, in which the evaluation unit 20 is integrated and fastened to a cable end at one end. The cable 2 is used generally in a conventional way as a data cable or else a supply cable. Monitoring of the cable 2 for the penetration of moisture is made possible through the use of the integrated capacitor 13 with the intermediate layer 10. Specifically in the integrated configuration according to FIG. 3, a pre-configured cable 2 is provided with integrated moisture monitoring.

1. A monitoring system, comprising:
a cable including a cable core, a multilayer sheath disposed around said cable core, said multilayer sheath including an inner electrode and an outer electrode of a capacitor, and a hygroscopic intermediate layer disposed between said electrodes; and
an evaluation unit configured to monitor said cable for moisture based on a capacitance of said capacitor.

2. The monitoring system according to claim 1, wherein said intermediate layer has a swellable material for absorbing moisture and leading to a change in a distance between said electrodes.

3. The monitoring system according to claim 1, wherein said intermediate layer has a superabsorber.

4. The monitoring system according to claim 1, wherein said intermediate layer has a thickness of less than 0.1 mm in a dry initial state.

5. The monitoring system according to claim 4, wherein said thickness increases by at least a factor of 10 or 20 until a moist final state of said intermediate layer is reached.

6. The monitoring system according to claim 1, wherein at least one of said electrodes is a screen layer.

7. The monitoring system according to claim 1, wherein at least one of said electrodes is permeable to moisture.

8. The monitoring system according to claim 7, wherein said at least one electrode is formed as a braid or a helix.

9. The monitoring system according to claim 1, wherein said inner electrode is permeable to moisture.

10. The monitoring system according to claim 9, wherein said inner electrode is formed as a braid or a helix.

11. The monitoring system according to claim 1, wherein said intermediate layer is extruded onto said inner electrode.

12. The monitoring system according to claim 1, wherein said sheath has an outer sheath layer of an elastic material.

13. The monitoring system according to claim 1, wherein said capacitor is not wired to an inductance present within said cable.

14. The monitoring system according to claim 1, wherein said evaluation unit:
is configured to measure the capacitance directly,
has an external inductance being wired to said capacitor of said cable to form a tuned circuit and is configured to measure a resonant frequency, and
is configured to output a measuring signal and evaluate a propagation time of the measuring signal.

15. A cable, comprising:
a cable core; and
a multilayer sheath disposed around said cable core, said multilayer sheath including an inner electrode and an outer electrode of a capacitor and a hygroscopic intermediate layer of a swellable material disposed between said electrodes.

16. The cable according to claim 15, which further comprises an integrated evaluation unit connected to said capacitor and configured to determine a capacitance of said capacitor.

17. The cable according to claim 16, which further comprises a connector, and a cable end fastened to said connector, said evaluation unit being disposed in said connector.
